(19) United States
(12) Patent Application Publication
(10) Pub. No.: US 2015/0228861 A1
(43) Pub. Date: Aug. 13, 2015

(54) LIGHT EMITTING DEVICE

(71) Applicant: Epistar Corporation, Hsinchu (TW)

(72) Inventors: Chih-Hao WEI, Hsinchu (TW); Yi-Luen HUANG, Hsinchu (TW)

(73) Assignee: Epistar Corporation, Hsinchu (TW)

(21) Appl. No.: 14/175,820

(22) Filed: Feb. 7, 2014

(51) Int. Cl. H01L 33/42; H01L 33/22; H01L 33/40

(52) U.S. Cl. CPC H01L 33/42; H01L 33/405; H01L 33/22; H01L 2933/0016

(57) ABSTRACT

A method for manufacturing a light-emitting device, comprising steps of: providing a semiconductor stack; forming an first conductive oxide layer on the semiconductor stack, wherein first conductive oxide layer has a top surface opposite to the semiconductor stack, and the top surface comprises a first region and a second region; forming a first layer contacting the first region of the top surface, wherein the first layer comprises a metal material; providing a first solution; forming a second layer by a reaction between the first solution, the first layer and the first conductive oxide layer; and removing the second layer to reveal the first region.

### TECHNICAL FIELD

The present application relates to a method of manufacturing a light-emitting device with a rough surface to improve the reliability thereof.

### DESCRIPTION OF BACKGROUND ART

Generally, the top surface of a light-emitting diode is roughened to reduce total reflection and improve the light extraction efficiency. The process of roughening the top surface includes dry etching and wet etching. Dry etching could control the roughening region precisely, but the cost is higher. The cost of wet etching is lower, but the top surface under the bonding pad is usually laterally etched during the process of wet etching and causes the peeling of the bonding pad easily.

As FIG. 1 shows, a light-emitting diode 1 comprises a substrate 8, a first semiconductor layer 12 having a first polarity, such as a n-type GaN layer, on the substrate 8, an active layer 10 for emitting light on the first semiconductor layer 12, a second semiconductor layer 11 having a second polarity, such as a p-type GaN layer, on the active layer 10, a conductive oxide layer 2 on the second semiconductor layer 11, and a second pad 9 is formed on the side of the substrate 8 opposite to the first semiconductor layer 12, wherein the conductive oxide layer 2 has a rough top surface 21 and a bonding pad 3 is formed on the top surface 21. When a portion of the top surface 21 under the bonding pad 3 is etched, the adhesion between top surface 21 and the bonding pad 3 decreased, and the bonding pad 3 is peeled easily from the top surface 21.

### SUMMARY OF THE DISCLOSURE

A method for manufacturing a light-emitting device, comprising steps of: providing a semiconductor stack; forming an first conductive oxide layer on the semiconductor stack, wherein first conductive oxide layer has a top surface opposite to the semiconductor stack, and the top surface comprises a first region and a second region; forming a first layer contacting the first region of the top surface, wherein the first layer comprises a metal material; providing a first solution; forming a second layer by a reaction between the first solution, the first layer and the first conductive oxide layer; and removing the second layer to reveal the first region.

### BRIEF DESCRIPTION OF THE DRAWINGS

FIG. 1 shows a light-emitting device according to prior art;

FIGS. 2a to 2f show a method of roughening an oxide layer of a light-emitting device according to first embodiment;

FIGS. 3a to 3c show the top view of the patterned metal layer;

FIGS. 4a to 4c show the top view of the second oxide layer.

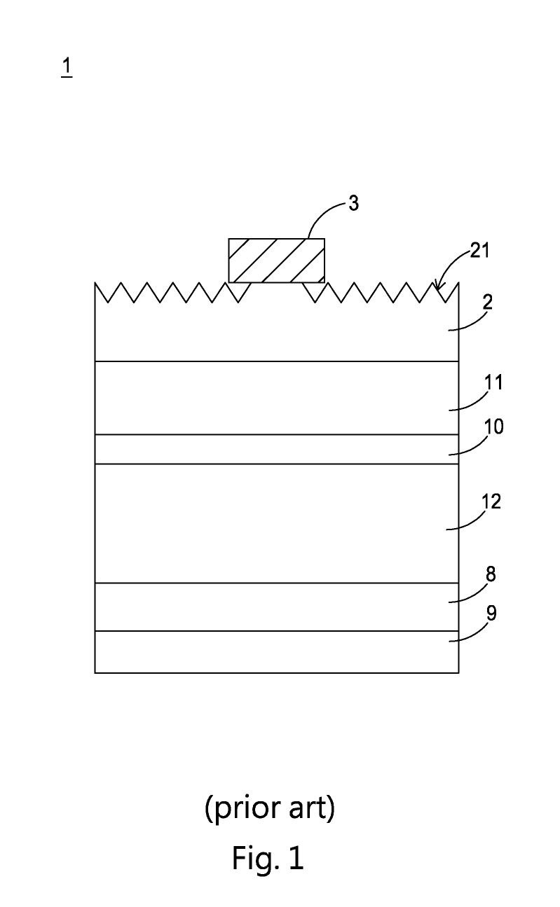

### DETAILED DESCRIPTION OF PREFERRED EMBODIMENTS

Exemplary embodiments of the present application will be described in detail with reference to the accompanying drawings hereafter. The following embodiments are given by way of illustration to help those skilled in the art fully understand the spirit of the present application. Hence, it should be noted that the present application is not limited to the embodiments herein and can be realized by various forms. Further, the drawings are not precise scale and components may be exaggerated in view of width, height, length, etc. Herein, the similar or identical reference numerals will denote the similar or identical components throughout the drawings.

### First Embodiment

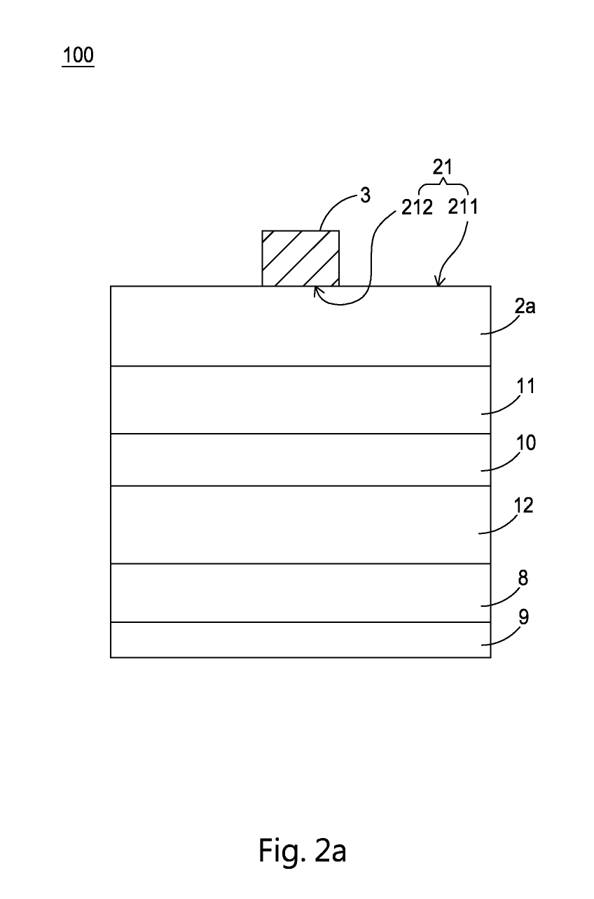

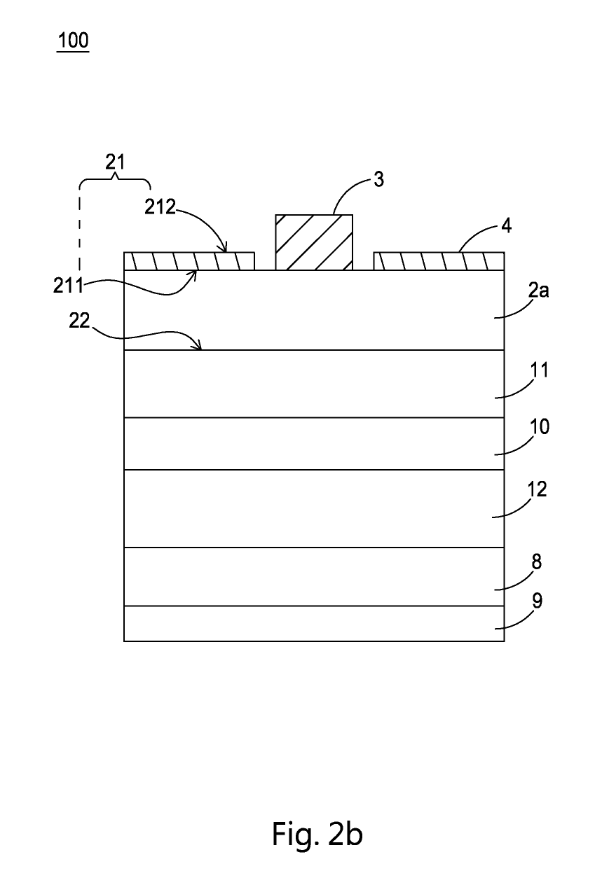

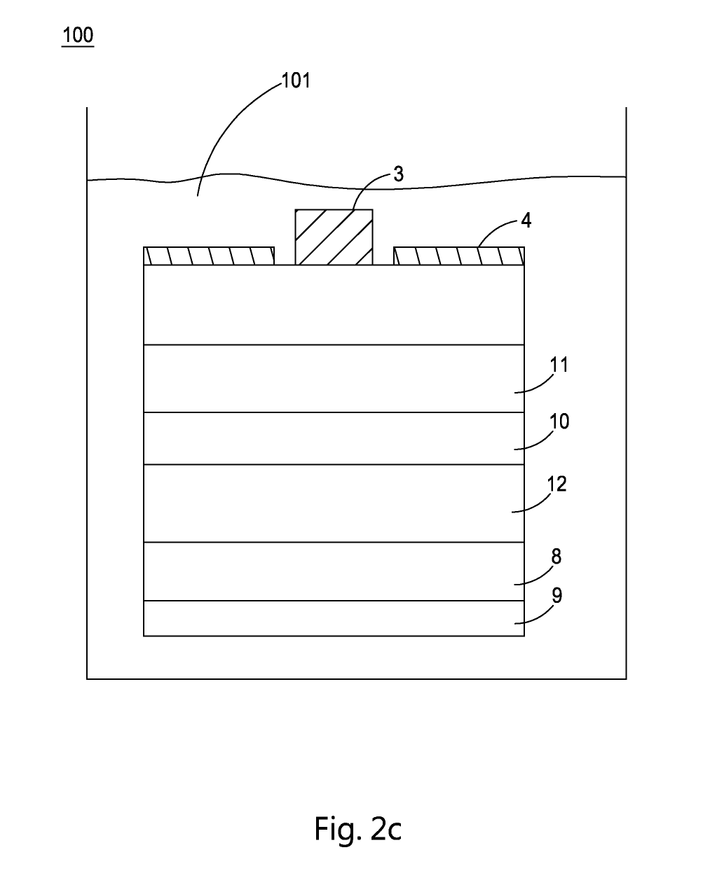

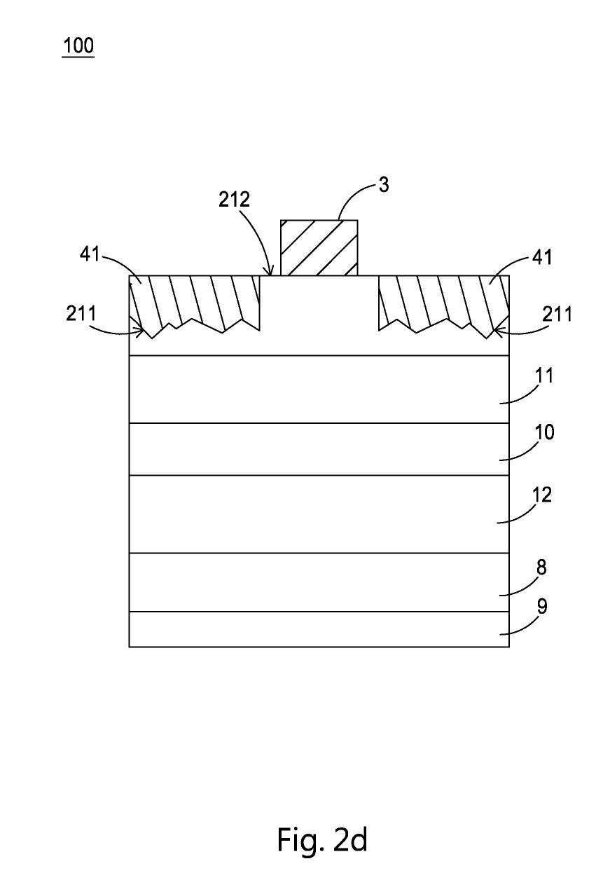

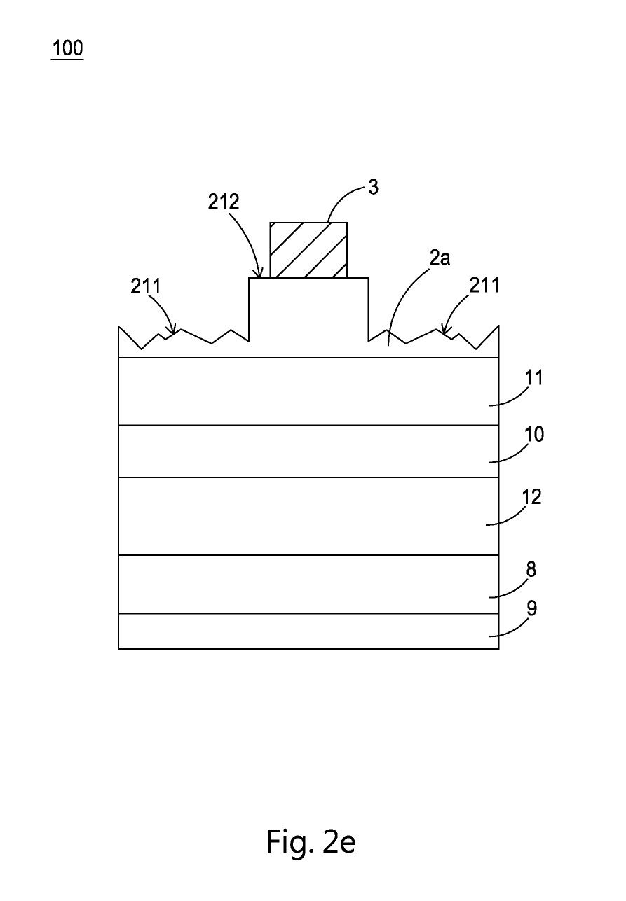

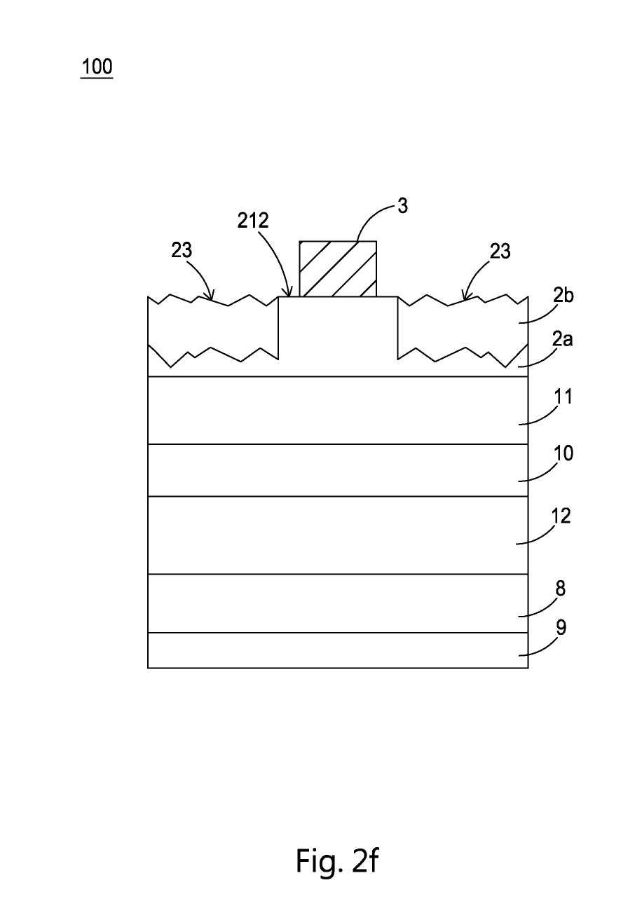

FIGS. 2a to 2f show a method of roughening an oxide layer of a vertical type light-emitting device. FIG. 2a shows the step of providing a vertical type light-emitting device 100. The light-emitting device 100 comprises a substrate 8, a first semiconductor layer 12 having a first polarity, such as an n-type GaN layer, on the substrate 8, an active layer 10 which can be a single heterostructure (SH) structure, a double heterostructure (DH) structure, a double-side double heterostructure (DDH) structure, or a multi-quantum well (MWQ) structure on the first semiconductor layer 12, a second semiconductor layer 11 having a second polarity, such as a p-type GaN layer, on the active layer 10, a first oxide layer 2a, such as indium tin oxide (ITO), on the second semiconductor layer 11. The first oxide layer 2a has a top surface 21, wherein the top surface 21 has a first region 211 and a second region 212, and a first pad is formed on the second region 212 and ohmically contacts with the first oxide layer 2a. A second pad 9 is formed on the side of the substrate 8 opposite to the first semiconductor layer 12, wherein the substrate 8 is electrically conductive and comprises a conductive material, such as metal, e.g. Cu, Al, In, Sn, Zn, W or the combination thereof, or semiconductor, e.g. Si, SiC, GaN, GaAs, etc.

The materials of the first semiconductor layer 12, the active layer 10, and the second semiconductor layer 11 comprise group III-V compound semiconductor, such as gallium phosphide (GaP), gallium arsenide (GaAs), or gallium nitride (GaN). The first semiconductor layer 12, the second semiconductor layer 11, or the active layer 10 may be formed by a known epitaxy method such as metallic-organic chemical vapor deposition (MOCVD) method, a molecular beam epitaxy (MBE) method, or a hydride vapor phase epitaxy (HVPE) method.

The material of the first oxide layer 2a comprises transparent conductive oxide material, such as indium tin oxide (ITO), cadmium tin oxide (CTO), antimony tin oxide, indium zinc oxide (IZO), zinc aluminum oxide, zinc oxide, and zinc tin oxide. The first oxide layer 2a is doped with a first impurity, wherein the first impurity comprises Sn, In, Al, Cd, or W. The first oxide layer 2a has a first transparency which depends on the concentration of the first impurity and the thickness of the first oxide layer 2a, and the first transparency is greater than 80% in the embodiment. The first oxide layer 2a is used for spreading the electrical current from the first pad 21. The first oxide layer 2a has a predetermined thickness such as smaller than 3000 angstroms and can be formed by a evaporation deposition method under chamber conditions of around room temperature, N₂ ambient environment, and a pressure between 1×10⁻⁴ Torr and 1×10⁻² Torr, or preferably around 5×10⁻³ Torr.

The first pad 3 and the second pad 9 are used for conducting an electrical current into the light-emitting device 100. Each of the first pad 3 and the second pad 9 comprises a bonding portion (not shown) for wire bonding and a conducting portion (not shown) for ohmically contacting the first oxide layer 2a or the substrate 8. In other embodiment, the first pad 3 or the second pad 9 further comprises a mirror portion for reflecting a light emitted from the active layer 10 or an adhesion layer for increasing the adhesion between the first pad 3 and the first oxide layer 2a or between the second pad 9 and the substrate 8.

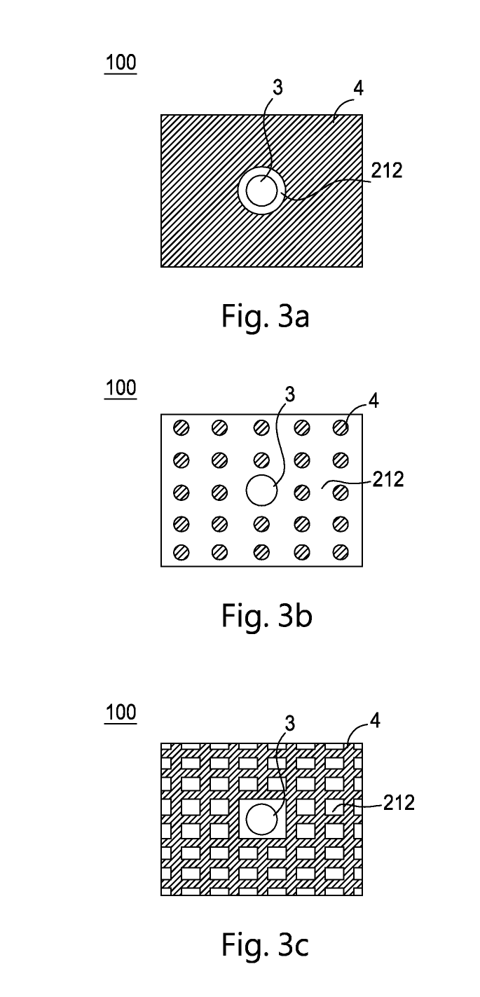

FIGS. 2b to 2e show a process of roughening a pattern region of the top surface 21 without damaging the first pad 3. FIG. 2b shows the step of forming a patterned metal layer 4 for covering the first region 211 of the top surface 21 and revealing the first pad 3 and a portion of the second region 212 where is not covered by the first pad 3. The pattern of the patterned metal layer 4 can be mesh or dot matrix. FIGS. 3a to 3c show the top view of the patterned metal layer 4 covering the first region 211 of the top surface 21. FIG. 3b shows the pattern of the patterned metal layer 4 can be dot matrix, and FIG. 3c shows the pattern of the patterned metal layer 4 can be mesh. The material of the patterned metal layer 4 comprises metal with high reactivity, such as Al or Ag.

FIG. 2c shows the step of providing a first solution 101 and immersing the light-emitting device 100 in the first solution 101. The first solution 101 triggers a chemical reaction of the patterned metal layer 4 and the first oxide layer 2a, such as reduction-oxidation reaction, to dope a second impurity into the first oxide layer 2a to form a second layer 41 on the first region 211 of the top surface 21, as shown in FIG. 2d. The second impurity comprises Al or Ag. The first impurity of the first oxide layer 2a can be completely or partially replaced by the second impurity during the chemical reaction. The second layer 41 has a second transparency smaller than the first transparency, and generally the second layer 41 can be opaque. The first solution 101 does not react with the first oxide layer 2a without the presence of the material of the patterned metal layer 4. The first solution 101 comprises H₂O and an organic base solution, such as AZ300T, wherein material of the organic base solution comprises a glycol, alkaline material or a nitrogenous organic compound. The reaction time or the thickness of the patterned metal layer 4 can determine the roughness of the first region 211. If the reaction time is longer, the first region 211 is rougher. If the patterned metal layer 4 is thicker, the first region 211 can also be rougher. For example, when the thickness of the first oxide layer 2a is 3000 Å, the thickness of patterned metal layer 4 is smaller than hum and preferably is between 200 Å and 300 Å, the roughness of the first region 211 can be controlled by the reacting time, wherein the reaction time is preferably smaller than 15 minutes.

FIG. 2e shows the step of removing the second layer 41 to reveal the first region 211 by using a second solution, wherein the second solution comprises buffered oxide etching solution (BOE) or phosphoric acid. The BOE is a mixture of a buffering agent, such as the mixture of ammonium fluoride (NH₄F) and hydrofluoric acid (HF). The first region 211 is rougher than the second region 212. The top view of the pattern of the first region 211 is the same as the pattern of the patterned metal layer 4 showed in FIGS. 3a to 3c. After the process of roughening the first region 211 of the top surface 21, the first oxide layer 2a in the first region 211 probably becomes discontinuous and the lateral conduction of the electrical current in the first oxide layer 2a is affected.

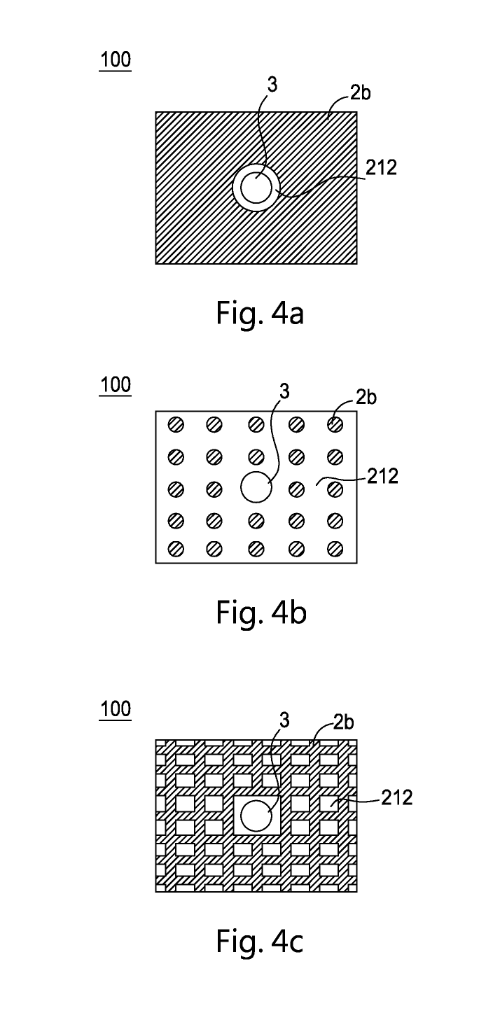

FIG. 2f shows the step of forming a second oxide layer 2b on the first region 211. The material of the second oxide layer 2b can be the same as or different from that of the first oxide layer 2a. The second oxide layer 2b comprises transparent conductive oxide material, such as indium tin oxide (ITO), cadmium tin oxide (CTO), antimony tin oxide, indium zinc oxide (IZO), zinc aluminum oxide, zinc oxide, and zinc tin oxide. The second oxide layer 2b is used for enhancing the lateral conduction of the electrical current in the first oxide layer 2a in the first region 211. The second oxide layer 2b comprises a second top surface 23, and the first region 211 is rougher than the second top surface 23, but the second top surface 23 is still rougher than the second region 212. FIG. 4 shows the top view of the second oxide layer 2b covering the first region 211 and without covering the second region 212 and the first pad 3. The pattern of the second oxide layer 2b is the same as the pattern of the patterned metal layer 4 showed in FIGS. 3a to 3c. The pattern of the second oxide layer 2b can be mesh or dot matrix. FIG. 4b shows the pattern of the second oxide layer 2b can be dot matrix, and FIG. 4c shows the pattern of the second oxide layer 2b can be mesh.

The foregoing description of preferred and other embodiments in the present disclosure is not intended to limit or restrict the scope or applicability of the inventive concepts conceived by the Applicant. In exchange for disclosing the inventive concepts contained herein, the Applicant desires all patent rights afforded by the appended claims. Therefore, it is intended that the appended claims include all modifications and alterations to the full extent that they come within the scope of the following claims or the equivalents thereof.

What is claimed is:

1. A method for manufacturing a light-emitting device, comprising steps of:
providing a semiconductor stack;
forming an first conductive oxide layer on the semiconductor stack, wherein first conductive oxide layer has a top surface opposite to the semiconductor stack, and the top surface comprises a first region and a second region;
forming a first layer contacting the first region of the top surface, wherein the first layer comprises a metal material;
providing a first solution;
forming a second layer by a reaction between the first solution, the first layer and the first conductive oxide layer; and
removing the second layer to reveal the first region.

2. The method for manufacturing a light-emitting device according to claim 1, wherein the first region is rougher than the second region after removing the second layer, and the concentration of the metal material in the first region is higher than that in the second region.

3. The method for manufacturing a light-emitting device according to claim 1, further comprising a step of providing a second solution for removing the second layer.

4. The method for manufacturing a light-emitting device according to claim 2, wherein the second solution comprises buffered oxide etching solution (BOE) or phosphoric acid.

5. The method for manufacturing a light-emitting device according to claim 1, wherein the first solution comprises an organic base material.

6. The method for manufacturing a light-emitting device according to claim 5, wherein the organic base material comprises a glycol, alkaline material or a nitrogenous organic compound.

7. The method for manufacturing a light-emitting device according to claim 5, wherein the first solution comprises a solvent.

8. The method for manufacturing a light-emitting device according to claim 5, wherein the solvent comprises water.

9. The method for manufacturing a light-emitting device according to claim 1, wherein the first conductive oxide layer comprises ITO, IZO, AZO or IWZO.

10. The method for manufacturing a light-emitting device according to claim 1, wherein the metal material comprises Al or Ag.

11. The method for manufacturing a light-emitting device according to claim 10, wherein the second layer comprises an oxide of the metal material.

12. The method for manufacturing a light-emitting device according to claim 1, further comprising a step of forming a second conductive layer on the first region.

13. The method for manufacturing a light-emitting device according to claim 12, wherein the second conductive oxide layer comprises a second top surface, and the first region is rougher than the second top surface.

14. The method for manufacturing a light-emitting device according to claim 12, wherein the first conductive oxide layer and the second conductive oxide layer comprise the same material.

15. A light-emitting diode, comprising:
a substrate;
a semiconductor stack on the substrate, wherein the semiconductor stack comprises a first semiconductor layer, an active layer for emitting a light, and a second semiconductor layer;
a first conductive oxide layer on the semiconductor stack, wherein the first conductive oxide layer has a top surface opposite to the semiconductor stack, and the top surface comprises a first region and a second region; and
a first pad on the second region;
wherein the first region is rougher than the second region,
wherein the first region of the first conductive oxide layer comprises a metal material while the second region of the first conductive oxide layer is devoid of the metal material.

16. A light-emitting diode according to claim 15, further comprising a second conductive oxide layer contacting the first region of the first conductive oxide layer, wherein the second conductive oxide layer is devoid of the metal material.

17. A light-emitting diode according to claim 15, wherein the first conductive oxide layer is a discontinuous structure.

18. A light-emitting diode according to claim 16, wherein the second conductive oxide layer has a second top surface and the first region is rougher than the second top surface.

19. A light-emitting diode according to claim 16, wherein the metal material exists between the first region of the first conductive oxide layer and the second conductive oxide layer.

20. A light-emitting diode according to claim 15, wherein the metal material comprises Al or Ag.
